(19) United States
(12) Patent Application Publication
(10) Pub. No.: US 2026/0150710 A1
(43) Pub. Date: May 28, 2026

(54) PACKAGE STRUCTURE

(71) Applicant: Advanced Semiconductor Engineering, Inc., Kaohsiung (TW)

(72) Inventors: Chia Hsiu HUANG, Taoyuan (TW); Kuang-Hsiung CHEN, Taoyuan (TW); Chun Chen CHEN, Taoyuan (TW); Shao-Lun YANG, Taoyuan (TW); Yueh-Chen HSU, Taoyuan (TW)

(73) Assignee: Advanced Semiconductor Engineering, Inc., Kaohsiung (TW)

(21) Appl. No.: 18/957,645

(22) Filed: Nov. 22, 2024

(51) Int. Cl. H01L 23/495; H01L 23/31

(52) U.S. Cl. CPC H10W 70/424; H10W 74/131

(57) ABSTRACT

The present disclosure relates to a package structure. The package structure includes a die, a leadframe and an encapsulant. The die includes a first surface and a second surface opposite to the first surface. The die includes a gate and a source on the first surface and a drain on the second surface. The leadframe includes a first lead connected to the gate and a second lead connected to the source. The encapsulant covering a lateral surface of the die and exposing the second surface of the die.

### BACKGROUND

### 1. Technical Field

The present disclosure relates generally to a package structure, and more particularly to a power device package including a power die accommodated in a leadframe cavity.

### 2. Description of the Related Art

Power devices generally include three terminals, two on one side and the third on the other. Current power device packages frequently use metal clips for connection, such that all three terminals can be routed to the same side for subsequent electrical connection. However, such packages prevent difficulty in size reduction, especially thickness, due to the size of the metal clips. Therefore, an improved power device package is called for.

### SUMMARY

In some embodiments, a package structure includes a die, a leadframe and an encapsulant. The die includes a first surface and a second surface opposite to the first surface. The die includes a gate and a source on the first surface and a drain on the second surface. The leadframe includes a first lead connected to the gate and a second lead connected to the source. The encapsulant covering a lateral surface of the die and exposing the second surface of the die.

In some embodiments, a package structure includes a power die and a leadframe. The power die includes a gate, a source, and a drain. The leadframe has a cavity accommodating the power die. A roughness of a bottom surface of the leadframe is different from a roughness of an inner surface of the cavity of the leadframe. The gate and the source of the power die face the inner surface of the cavity.

In some embodiments, a package structure includes a power die and a leadframe. The leadframe has a cavity. An inner surface of the cavity of the leadframe has a plurality of recesses. The power die is accommodated in the cavity of the leadframe. The power die includes a gate and a source facing the plurality of recesses.

### BRIEF DESCRIPTION OF THE DRAWINGS

Aspects of the present disclosure are readily understood from the following detailed description when read with the accompanying figures. It should be noted that various features may not be drawn to scale. The dimensions of the various features may be arbitrarily increased or reduced for clarity of discussion.

FIG. 1A is a cross-section of a package structure, in accordance with some embodiments of the present disclosure.

FIG. 1B is an enlarged perspective view of a region “1B” in FIG. 1A, in accordance with some embodiments of the present disclosure.

FIG. 1C is an enlarged perspective view of a region “1C” in FIG. 1A, in accordance with some embodiments of the present disclosure.

FIG. 1D is a bottom view of a package structure, in accordance with some embodiments of the present disclosure.

FIG. 2 is a cross-section of a package structure, in accordance with some embodiments of the present disclosure.

FIG. 3A is a cross-section of a package structure, in accordance with some embodiments of the present disclosure.

FIG. 3B is a cross-section of a package structure, in accordance with some embodiments of the present disclosure.

FIG. 3C is a bottom view of a package structure, in accordance with some embodiments of the present disclosure.

FIG. 4A, FIG. 4B, FIG. 4C, FIG. 4D, FIG. 4E, FIG. 4F, and FIG. 4G illustrate one or more operations of a method for manufacturing a package structure, in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

The following disclosure provides different embodiments, or examples, for implementing different features of the provided subject matter. Specific examples of components and embodiments are recited herein. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may be formed between the first and second features, such that the first and second features may not be in direct contact. The present disclosure may repeat reference numerals and/or letters in the various examples. This repetition is for simplicity and clarity and does not in itself dictate a relationship between the various embodiments and/or configurations discussed.

Embodiments of the present disclosure are discussed in detail as follows. It should be appreciated, however, that the present disclosure provides many applicable concepts that can be embodied in a wide variety of specific contexts. The specific embodiments discussed are merely illustrative and do not limit the scope of the disclosure.

The total size of power device packages may be reduced by use of a half-etched leadframe. In particular, the leadframe may be etched to form a space (such as a cavity) accommodating the power die. The terminals of the power die can be connected to the opposite side of the power die through the etched leadframe, whereby all three terminals of the power device are located on the same surface for subsequent connection. Thickness of the power device package can thus be decreased.

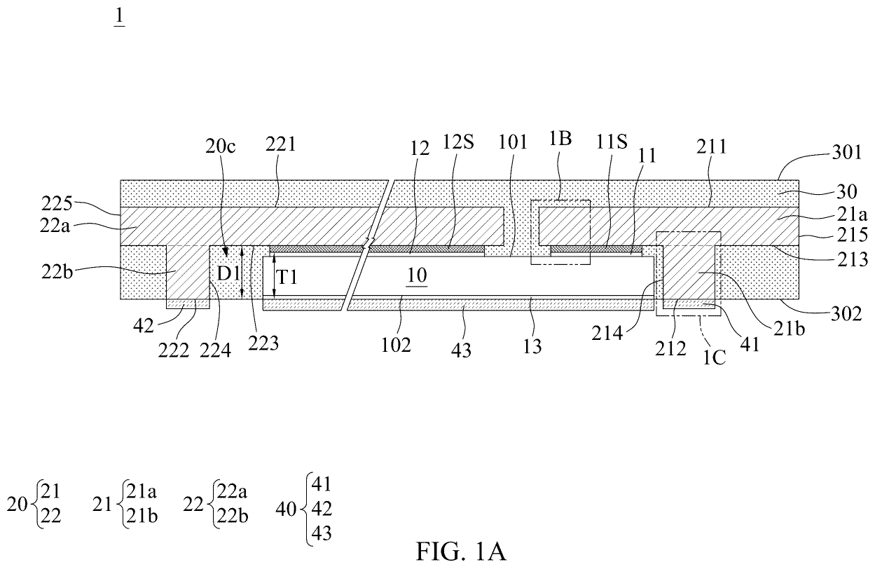

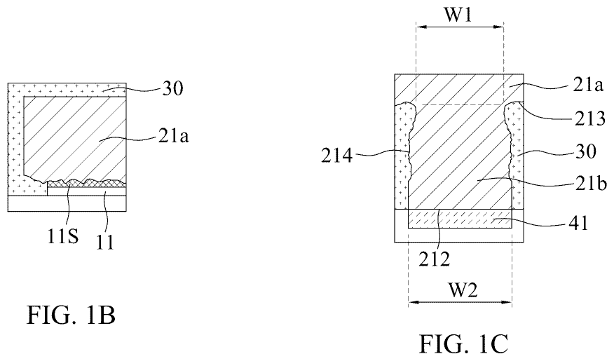

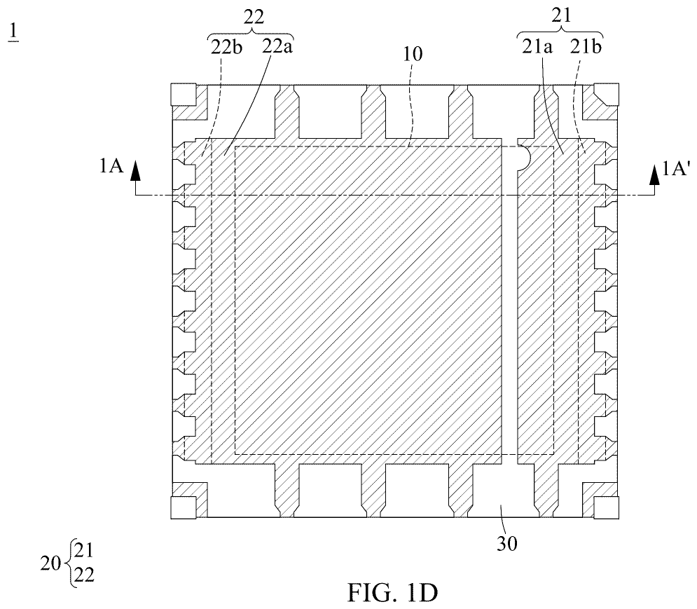

FIG. 1A is a cross-section of a package structure 1, in accordance with some embodiments of the present disclosure. FIG. 1B is an enlarged perspective view of a region “1B” in FIG. 1A, in accordance with some embodiments of the present disclosure. FIG. 1C is an enlarged perspective view of a region “1C” in FIG. 1A, in accordance with some embodiments of the present disclosure. FIG. 1D is a bottom view of a package structure 1, in accordance with some embodiments of the present disclosure. FIG. 1A is a cross-section of the package structure 1 along line 1A-1A′ of FIG. 1D.

Referring to FIG. 1A, the package structure 1 may include a die 10, a leadframe 20, an encapsulant 30, and a conductive layer 40.

In some embodiments, the die 10 may have a top surface 101 and a bottom surface 102 opposite to the top surface 101. The die 10 may include a gate 11 and a source 12 on the top surface 101 and a drain 13 on the bottom surface 102. The gate 11 and the source 12 may be conductive pads protruding from or embedded in the top surface 101. The drain 13 may be conductive pads protruding from or embedded in the bottom surface 102. The die 10 may be a power die. In some embodiments, the die 10 may include a transistor, such as a MOSFET. In some embodiments, the package structure 1 may be a power device package.

In some embodiments, the leadframe 20 may include a first lead 21 connected to the gate 11 and a second lead 22 connected to the source 12. In some embodiments, the first lead 21 is spaced apart from the second lead 22. The first lead 21 and the second lead 22 may be a T-shape in cross-section. The first lead 21 and the second lead may be of a conductive material, such as a metal or a metal alloy.

The first lead 21 of the leadframe 20 may have a top surface 211, a bottom surface 212 opposite to the top surface 211, and a surface 213 between the top surface 211 and the bottom surface 212, a lateral surface 214 connecting the bottom surface 212 and the surface 213, and a lateral surface 215 connecting the top surface 211 and the surface 213. The top surface 211 may be substantially parallel to the bottom surface 212. The surface 213 may be substantially parallel to the bottom surface 212. The inner lateral surface 214 may be substantially perpendicular to the surface 213 and the bottom surface 212. The lateral surface 215 may be substantially perpendicular to the top surface 211 and the surface 213. The die 10 may be disposed between the surface 213 and the bottom surface 212.

The first lead 21 may include a first portion 21a and a second portion 21b. The first portion 21a of the first lead 21 may be connected to the gate 11 and extend horizontally. The second portion 21b may be connected to the first portion 21a and extend vertically toward the bottom surface 102 of the die 10. The second portion 21b may be a terminal for routing the gate 11 of the die 10 to the bottom surface 212. In some embodiments, the first portion 21a may extend perpendicular to the second portion 21b. In some embodiments, the first lead 21 may be connected to and attached to the gate 11 of the die 10 through a solder material 11S. The solder material 11S may include solder balls, solder paste, and the like. The solder material 11S may include solder paste, solder bumps, or solder ball, or non-solder conductive structures such as copper pillar, or a combination thereof.

In some embodiments, the second lead 22 of the leadframe 20 may have a top surface 221, a bottom surface 222 opposite to the top surface 221, and a surface 223 between the top surface 221 and the bottom surface 222, a lateral surface 224 connecting the bottom surface 222 and the surface 223, and a lateral surface 225 connecting the top surface 221 and the surface 223. The top surface 221 may be substantially parallel to the bottom surface 222. The surface 223 may be substantially parallel to the bottom surface 222. The inner lateral surface 224 may be substantially perpendicular to the surface 223 and the bottom surface 222. The lateral surface 225 may be substantially perpendicular to the top surface 221 and the surface 223. The die 10 may be disposed between the surface 223 and the bottom surface 222.

The second lead 22 may include a first portion 22a and a second portion 22b. The first portion 22a of the second lead may be connected to the gate 11 and extend horizontally. The second portion 22b may be connected to the first portion 22a and extend vertically toward the bottom surface 102 of the die 10. In some embodiments, the first portion 22a may extend perpendicular to the second portion 22b. In some embodiments, the second lead 22 may be connected to and attached to the source 12 of the die 10 through a solder material 12S. The solder material 12S may include solder balls, solder paste, and the like. The solder material 12S may include solder paste, solder bumps, or solder ball, or non-solder conductive structures such as copper pillar, or a combination thereof.

The leadframe 20 may have a cavity 20c accommodating the die 10. In some embodiments, the cavity 20c may be formed by the first lead 21 and the second lead 22. In some embodiments, the first lead 21 and the second lead 22 may be etched to form a specific shape (i.e., the cavity 20c) to accommodate the die 10. In some embodiments, the first lead 21 and the second lead 22 may be half-etched. In some embodiments, a depth D1 of the cavity 20c may be greater than a thickness T1 of the die 10 in cross-section. In some embodiments, the depth D1 of the cavity 20c may be defined by a length of the second portion 21b vertically.

In some embodiments, an electrical path may be established from the gate 11 of the die 10 to the bottom surface 212 of the first lead 21 of the leadframe 20 through the surface 213 of the first lead 21 of the leadframe 20. In some embodiments, an electrical path may be established from the source 12 of the die 10 to the bottom surface 222 of the second lead 22 of the leadframe 20 through the surface 223 of the second lead 22 of the leadframe 20. Accordingly, the gate 11 and the source 12 may be routed to the same side of die 10 as drain 13.

The first lead 21 may be configured to provide a first terminal (for example, the second portion 21b) for the gate 11 of the die 10 and the second lead 22 may be configured to provide a second terminal (for example, the second portion 22b) for the source 12 of the die 10, wherein the first terminal and the second terminal are located at opposite sides of the die 10 and at the same elevation as the drain 13 in cross-section. In other words, the gate 11 and the source 12 may be routed to the side of the die 10 (i.e., the bottom surface 102) through the leadframe 20.

Referring to FIGS. 1B and 1C, due to etching, the surface 213 of the first portion 21a of the first lead 21 that face the die 10 may have multiple recesses, and the lateral surface 214 of the second portion 21b of the first lead 21 may also have multiple recesses. In some embodiments, the surface 213 may directly contact the solder material 21S to connect the gate 11 of the die. Therefore, an interface of the first lead 21 and the solder material 21S may be irregular. In some embodiments, a roughness of the bottom surface 212 of the leadframe 20 is different from a roughness of the surface 213 or 214 (i.e., inner surfaces of the cavity 20c) of the first lead 21 of the leadframe 20. For example, the roughness of the bottom surface 212 of the first lead 21 is greater than the roughness of the surface 213 or 214 of the first lead 21. In some embodiments, the surface 212 may be protected/masked, and thus the roughness may not be affected.

In some embodiments, the neck portion of the leadframe 20 may be thin during etching. For example, the second portion 21b of the first lead 21 may have a minimum width at where the second portion 21b connecting the first portion 21a in cross-section. In some embodiments, the second portion 21b may have a first width W1 adjacent to the first portion 21a and a second width W2 adjacent to the bottom surface 212 of the first lead 21, wherein the first width W1 is less than the second width W2.

The second lead 22 may have the same details as the first lead 21, with details thereof not repeated for brevity. Correspondingly, the surface 223 and lateral surface 224 of the second lead 22 may have multiple recesses and a roughness different from that of the bottom surface 222 of the leadframe 20.

Referring back to FIG. 1A, the encapsulant 30 may cover or encapsulate the die 10 and the leadframe 20. In some embodiments, the encapsulant 30 may cover or encapsulate lateral surfaces of the die 10. The encapsulant 30 may expose the bottom surface 102 of the die 10. The encapsulant 30 may expose the bottom surfaces 212 and 222 of the leadframe 20. In some embodiments, the top surfaces 211 and 221 of the leadframe 20 are covered by the encapsulant 30. For example, the top surfaces 211 and 221 of the leadframe 20 may be entirely covered by the encapsulant 30. In some embodiments, the encapsulant 30 may be filled between the first lead 21 and the second lead 22. In some embodiments, the first lead 21 and the second lead 22 may define a gap therebetween. The encapsulant 30 may be disposed over and covers the gap. The gap non-overlaps a centerline of the die 10 vertically.

In some embodiments, the encapsulant 30 may include an epoxy resin, a molding compound (e.g., an epoxy molding compound or other molding compound), a polyimide, a phenolic compound or material, a material including a silicone dispersed therein, or a combination thereof.

In some embodiments, the encapsulant 30 may have a top surface 301 and a bottom surface 302 opposite to the top surface 301. The bottom surface 302 of the encapsulant 30 may substantially align with bottom surface 102 of the die 10. The lateral surface 214 may be covered by the encapsulant 30. The first portion 21a of the first lead 21 may have the lateral surface 215 exposed by the encapsulant 30. The first portion 22a of the second lead 22 may have lateral surface 225 exposed by the encapsulant 30.

In some embodiments, the conductive layer 40 may be disposed on the bottom surface 102 of the die 10. The drain 13 of the die 10 may be covered by the conductive layer 40. The conductive layer 40 may be disposed on the bottom surface 212 of the first lead 21 and the bottom surface 222 of the second lead 22 that are exposed by the encapsulant 30. The conductive layer 40 may protrude from the encapsulant 30. In some embodiments, the conductive layer 40 may be formed by electroplating. The conductive layer 40 may include metal or alloy, such as silver, tin, or other suitable material.

In some embodiments, the conductive layer 40 may include a first portion 41, a second portion 42, and a third portion 43. The first portion 41 may be attached to or disposed on the bottom surface 212 of the first lead 21 of the leadframe 20. The second portion 42 may be attached to or disposed on the bottom surface 222 of the second lead 22 of the leadframe 20 and spaced apart from the first portion 41. The second portion 42 of the conductive layer 40 may substantially align with the first portion 41. In some embodiments, a thickness of the second portion 42 may be substantially identical to a thickness of the first portion 41. The third portion 43 may be attached to or disposed on the bottom surface 102 of the die 10 and spaced apart from the first portion 41 and the second portion 42. The third portion 43 of the conductive layer 40 may substantially align with the first portion 41. In some embodiments, a thickness of the third portion 43 may be substantially identical to a thickness of the first portion 41. In some embodiments, the first portion 41, the second portion 42, and the third portion 43 of the conductive layer 40 may be configured to provide electrical connection.

The leadframe 20 is half-etched to form a cavity 20c accommodating the die 10. Accordingly, three terminals of the die 10 can be routed to the same side through the etched leadframe 20 for subsequent connection. Half-etching can be controlled to form a cavity 20c having a size matching the die 10. Therefore, the total size (for example, the thickness) of the package structure may be reduced.

FIG. 1D is a bottom view of a package structure 1, which, for brevity, omits the die 10, conductive layer 40, and the encapsulant 30 covered on the leadframe 20. Referring to FIG. 1D, the first lead 21 of the leadframe 20 may be disposed at a side of the die 10, and the second lead 22 of the leadframe 20 may be disposed at an opposite side of the die 10 and spaced apart from the first lead 21. In some embodiments, an area of the first lead 21 may be less than an area of the second lead 22.

The second portion 21b of the first lead 21 may be a terminal for the gate 11 of the die 10. The second portion 22b of the second lead 22 may be a terminal for the source 12 of the die 10. The second portion 21b of the first lead 21 may be configured route the gate 11 to the same side of the die 10 as drain 13. The second portion 22b of the second lead 22 may be configured to route the source 12 to the same side of the die 10 as drain 13. In some embodiments, an area of the second portion 21b of the first lead 21 may be substantially identical to an area of the second portion 22b of the second lead 22. In other words, the area of the second portion 21b of the first lead 21 and the area of the second portion 22b of the second lead 22 that are exposed by the encapsulant 30 may be substantially the same. In some embodiments, the first lead 21 and the second lead 22 may have one or more terminals extending horizontally and vertically for electrical connection.

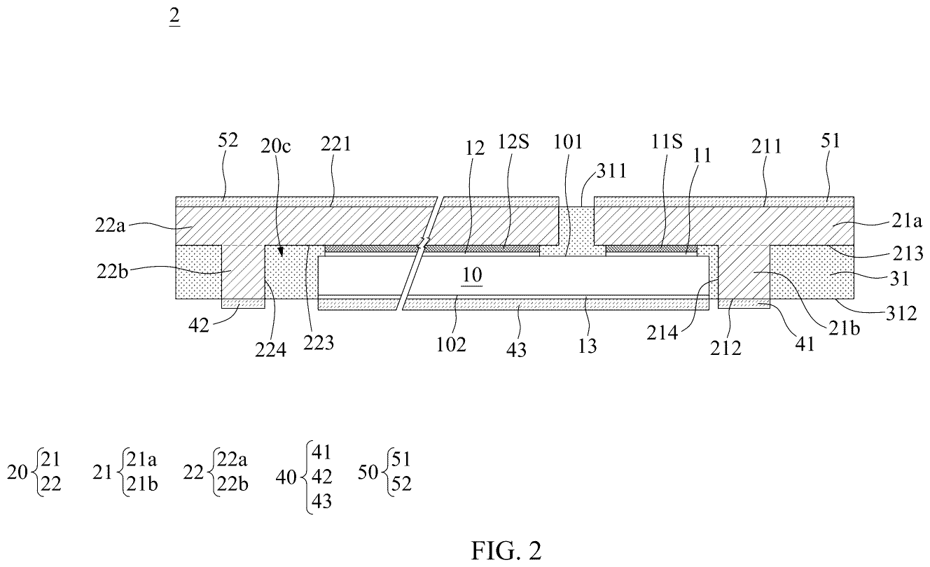

FIG. 2 is a cross-section of a package structure 2, in accordance with some embodiments of the present disclosure. The package structure 2 of FIG. 2 is similar to the package structure 1 of FIGS. 1A-1D, but with different arrangement of the encapsulant and an additional conductive layer.

In some embodiments, the package structure 2 may include an encapsulant 31 exposing the top surfaces 211 and 221 of the leadframe 20 and a conductive layer 50. In some embodiments, the encapsulant 31 is similar to the encapsulant 30 in FIGS. 1A-1D, and may not cover the top surface 211 of the first lead 21 and the top surface 221 of the second lead 22. The encapsulant 31 may have a top surface 311 and a bottom surface 312 opposite to the top surface 311. The top surface 311 may substantially align with the top surfaces 211 and 221 of the leadframe 20. The bottom surface 312 may substantially align with the bottom surfaces 212 and 222 of the leadframe 20.

In some embodiments, the conductive layer 50 may be disposed on the top surface 101 of the die 10. The conductive layer 50 may be disposed on the top surface 211 of the first lead 21 and the top surface 221 of the second lead 22 that are exposed by the encapsulant 31. The conductive layer 50 may protrude from the encapsulant 31. In some embodiments, the conductive layer 50 may be formed by electroplating. The conductive layer 50 may include metal or alloy, such as silver, tin, or other suitable material.

In some embodiments, the conductive layer 50 may include a first portion 51 and a second portion 52. The first portion 51 may be attached to or disposed on the top surface 211 of the first lead 21 of the leadframe 20. The second portion 52 may be attached to or disposed on the top surface 221 of the second lead 22 of the leadframe 20 and spaced apart from the first portion 51. The second portion 52 of the conductive layer 50 may substantially align with the first portion 51 horizontally. That is, a thickness of the second portion 52 may be substantially identical to a thickness of the first portion 51. In some embodiments, the first portion 51 and the second portion 52of the conductive layer 50 may be configured to provide electrical connection.

The package structure 2 can be reduced in size by use of a thinner encapsulant 31. By incorporating the conductive layers 50 and 40 on opposite sides of the leadframe 20, the package structure 2 may have a flexible electrical connection.

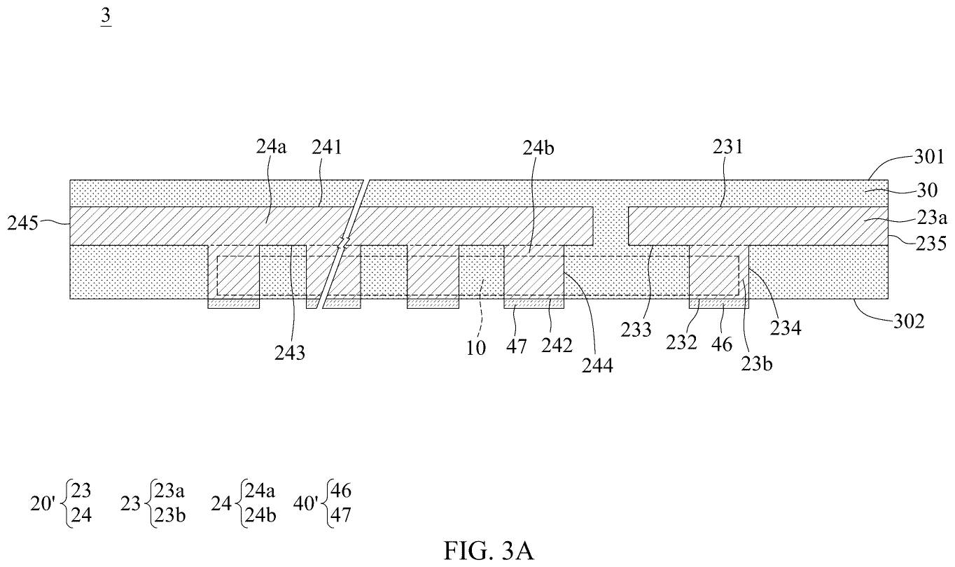

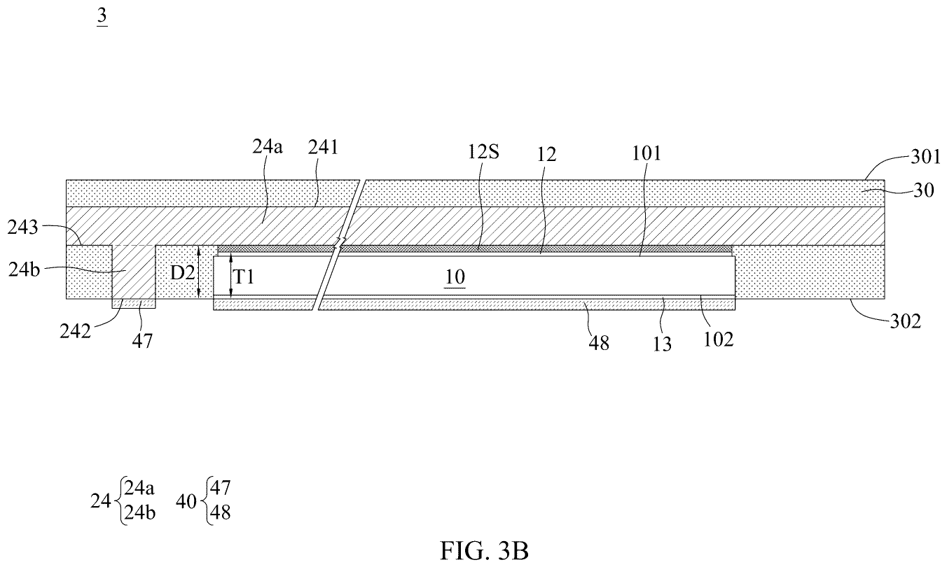

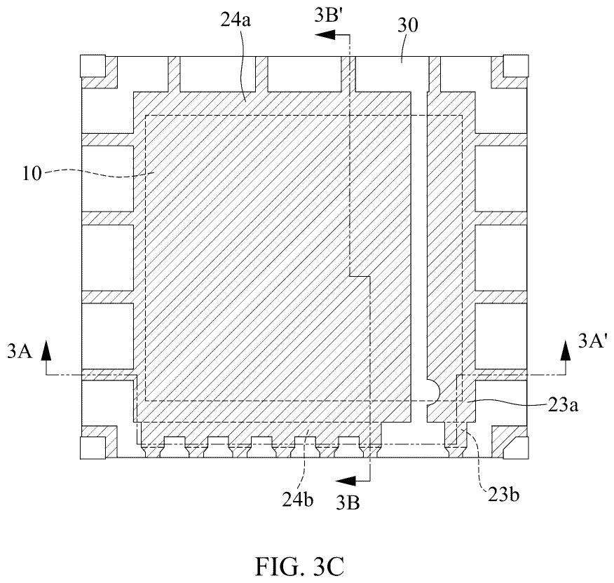

FIG. 3A is a cross-section of a package structure 3, in accordance with some embodiments of the present disclosure. FIG. 3B is a cross-section of a package structure 3, in accordance with some embodiments of the present disclosure. FIG. 3C is a bottom view of a package structure 3, in accordance with some embodiments of the present disclosure. FIG. 3A is a cross-section of the package structure 3 along line 3A-3A′ of FIG. 3C, and FIG. 3B is a cross-section of the package structure 3 along line 3B-3B′ of FIG. 3C.

The package structure 3 of FIGS. 3A-3C is similar to the package structure 1 of FIGS. 1A-1D, but with different arrangement of the leadframe. Referring to FIGS. 3A-3C, the package structure 3 may include a leadframe 20′ and a conductive layer 40′. In some embodiments, the leadframe 20′ may include a first lead 23 and a second lead 24. In some embodiments, the conductive layer 40′ may include a first portion 46, a second portion 47, and a third portion 48. For clarity, FIG. 3C omits the die 10, the conductive layer 40′, and the encapsulant 31 that is covered on the leadframe 20′.

Referring to FIGS. 3A and 3C, the first lead 23 may be disposed at a side of the die 10 and the second lead 24 may be disposed at the opposite side of the die 10. The first lead 23 may be connected to the gate 11 (not shown) of the die 10. The second lead 24 may be connected to the source 12 of the die 10 (see FIG. 3B). In some embodiments, the first lead 23 is spaced apart from the second lead 24.

The first lead 23 of the leadframe 20′ may have a top surface 231, a bottom surface 232 opposite to the top surface 231, and a surface 233 between the top surface 231 and the bottom surface 232, a lateral surface 234 connecting the bottom surface 232 and the surface 233, and a lateral surface 235 connecting the top surface 231 and the surface 233. The top surface 231 may be substantially parallel to the bottom surface 232. The surface 233 may be substantially parallel to the bottom surface 232. The lateral surface 234 may be substantially perpendicular to the surface 233 and the bottom surface 232. The lateral surface 235 may be substantially perpendicular to the top surface 231 and the surface 233. The die 10 may be disposed between the surface 233 and the bottom surface 232.

The first lead 23 may include a first portion 23a and a second portion 23b. The first portion 23a of the first lead 23 may be connected to the gate 11 (not shown) and extend horizontally. The second portion 23b may be connected to the first portion 23a and extend vertically toward the bottom surface 102 of the die 10. The second portion 23b may be a terminal for routing the gate 11 of the die 10 to the bottom surface 232. In other words, the gate 11 may be routed to the same side of the bottom surface 102 of the die 10 through the second portion 23b of the first lead 23. In some embodiments, the second portion 23b may extend perpendicular to the first portion 23a.

The second lead 24 of the leadframe 20′ may have a top surface 241, a bottom surface 242 opposite to the top surface 241, and a surface 243 between the top surface 241 and the bottom surface 242, a lateral surface 244 connecting the bottom surface 242 and the surface 243, and a lateral surface 245 connecting the top surface 241 and the surface 243. The top surface 241 may be substantially parallel to the bottom surface 242. The surface 243 may be substantially parallel to the bottom surface 242. The lateral surface 244 may be substantially perpendicular to the surface 243 and the bottom surface 242. The lateral surface 245 may be substantially perpendicular to the top surface 241 and the surface 243. The die 10 may be disposed between the surface 243 and the bottom surface 242.

Referring to FIGS. 3A and 3B, the second lead 24 may include a first portion 24a and a second portion 24b. The first portion 24a of the second lead 24 may be connected to the source 12 and extend horizontally. The second portion 24b may be connected to the first portion 24a and extend vertically toward the bottom surface 102 of the die 10. The second portion 24b may be a terminal for routing the source 12 of the die 10 to the bottom surface 242. In other words, the source 12 may be routed to the same side of the bottom surface 102 of the die 10 through the second portion 24b of the second lead 24. In some embodiments, the second portion 24b may extend perpendicular to the first portion 24a.

In some embodiments, the first lead 23 and the second lead 24 may be etched to form a specific shape to accommodate the die 10. In some embodiments, the first lead 23 and the second lead 24 may be half-etched. In some embodiments, a length D2 of the second lead 24 may be greater than the thickness T1 of the die 10 in cross-section.

The first lead 23 may be configured to provide a first terminal (for example, the second portion 23b) for the gate 11 of the die 10 and the second lead 24 may be configured to provide a second terminal (for example, the second portion 24b) for the source 12 of the die 10. The first terminal and the second terminal are located at the same side of the die 10 (see FIGS. 3A and 3C). In some embodiments, the first terminal (i.e., the second portion 23b) and the second terminal (i.e., the second portion 24b) may be located at the same lateral side of the die 10.

Referring to FIG. 3C, an area of the first terminal (the second portion 23b) may be less than an area of the second terminal (the second portion 24b). In some embodiments, the first lead 23 may have one terminal and the second lead 24 may have six terminals. In other embodiments, the number of the terminals of the first lead 23 and the second lead 24 may be modified according to need.

Referring to FIGS. 3A and 3B, the conductive layer 40′ may be disposed on the bottom surface 102 of the die 10. The drain 13 of the die 10 may be covered by the conductive layer 40′. The conductive layer 40′ may be disposed on the bottom surface 232 of the first lead 23 and the bottom surface 242 of the second lead 24 that are exposed by the encapsulant 30. The conductive layer 40′ may protrude from the encapsulant 30. In some embodiments, the conductive layer 40′ may be similar to the conductive layer 40. In some embodiments, the conductive layer 40′ may be formed by electroplating. The conductive layer 40′ may include metal or alloy, such as silver, tin, or other suitable material.

In some embodiments, the conductive layer 40′ may include a first portion 46, a second portion 47, and a third portion 48. The first portion 46 may be attached to or disposed on the bottom surface 232 of the first lead 23. The second portion 47 may be attached to or disposed on the bottom surface 242 of the second lead 24 and spaced apart from the first portion 46. The second portion 47 of the conductive layer 40′ may substantially align with the first portion 46. In some embodiments, a thickness of the second portion 47 may be substantially identical to a thickness of the first portion 46. Referring to FIG. 3B, the third portion 48 may be attached to or disposed on the bottom surface 102 of the die 10 and spaced apart from the second portion 47. The third portion 48 of the conductive layer 40′ may substantially align with the second portion 47. Similarly, the third portion 48 of the conductive layer 40′ may be spaced apart from the first portion 46. In some embodiments, a thickness of the third portion 48 may be substantially identical to a thickness of the first portion 46. In some embodiments, the first portion 46, the second portion 47, and the third portion 48 of the conductive layer 40′ may be configured to provide electrical connection.

The leadframe 20′ is half-etched to form a space accommodating the die 10. Accordingly, three terminals on opposite surfaces of the die 10 can be routed to the same (vertical) side through the etched leadframe 20′. Half-etching can be controlled to form a space suitable to the die 10. Therefore, the total size (for example, the thickness) of the package structure may be reduced. In addition, the terminals of the leadframe 20′ can be located at the same (lateral) side of the die 10, such that the package structure 3 would obtain flexible electrical connection.

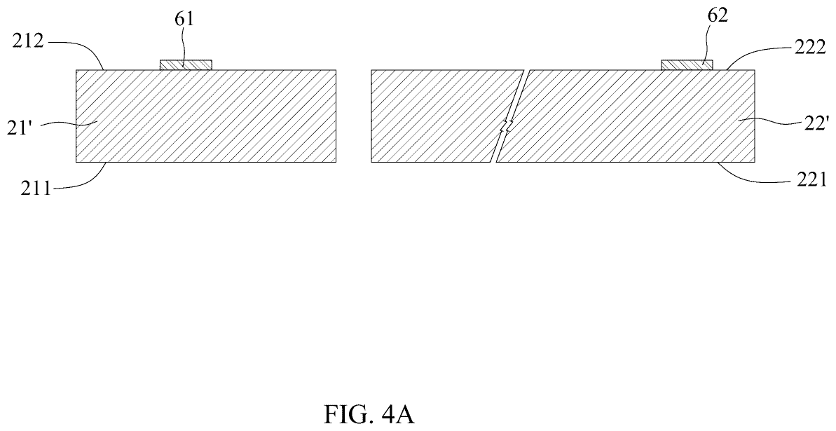

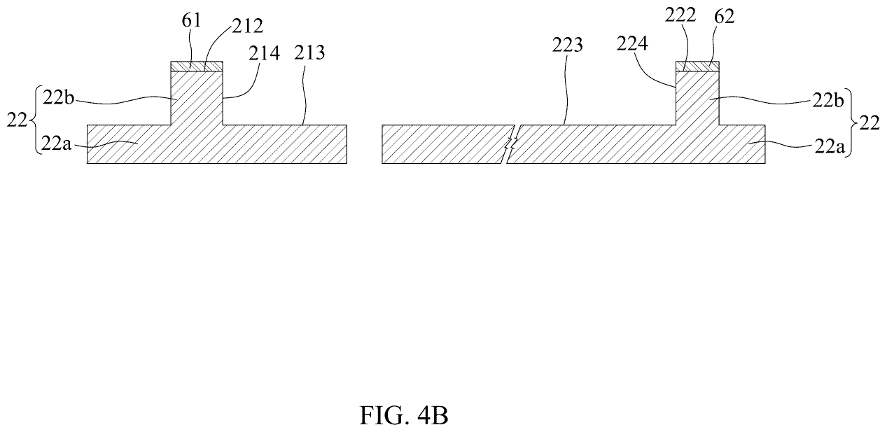

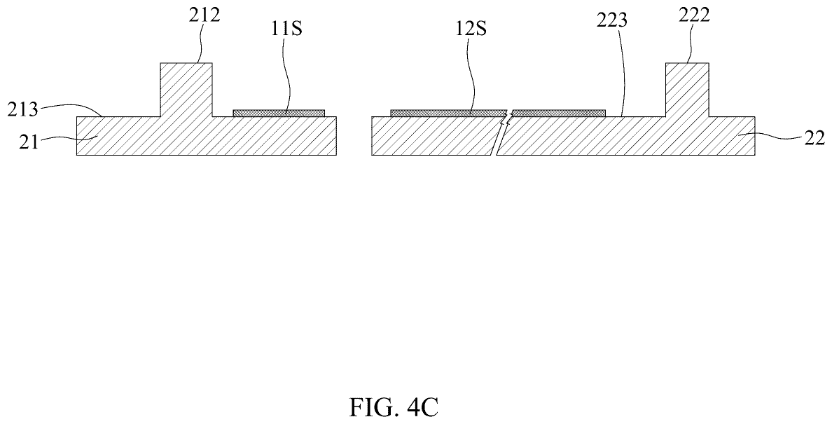

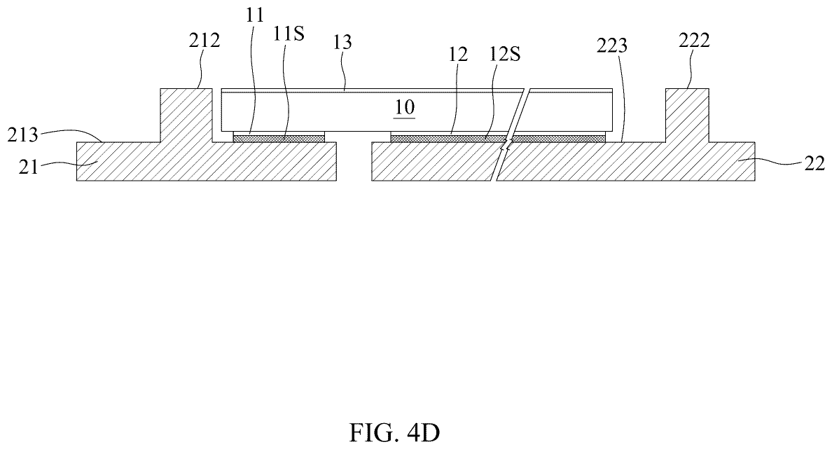

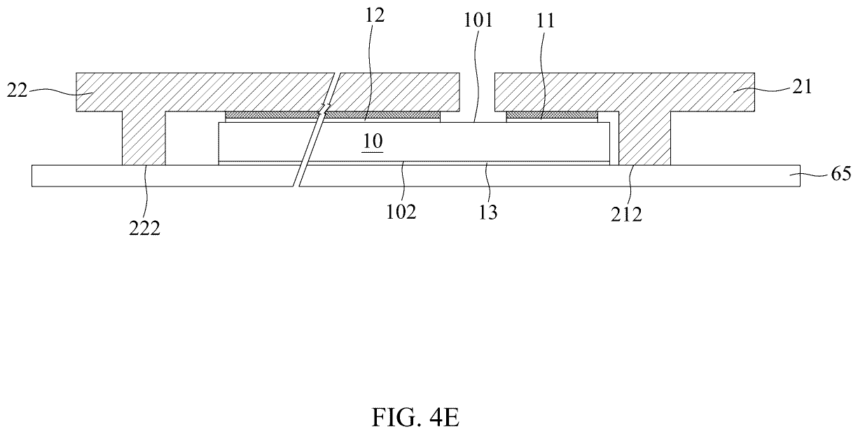

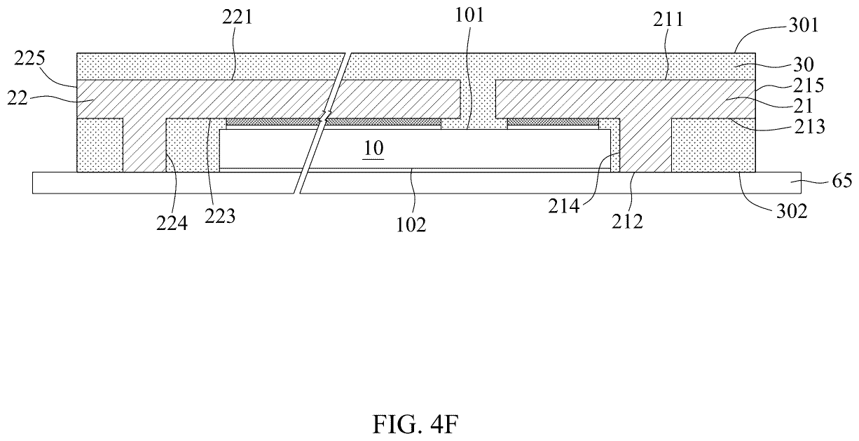

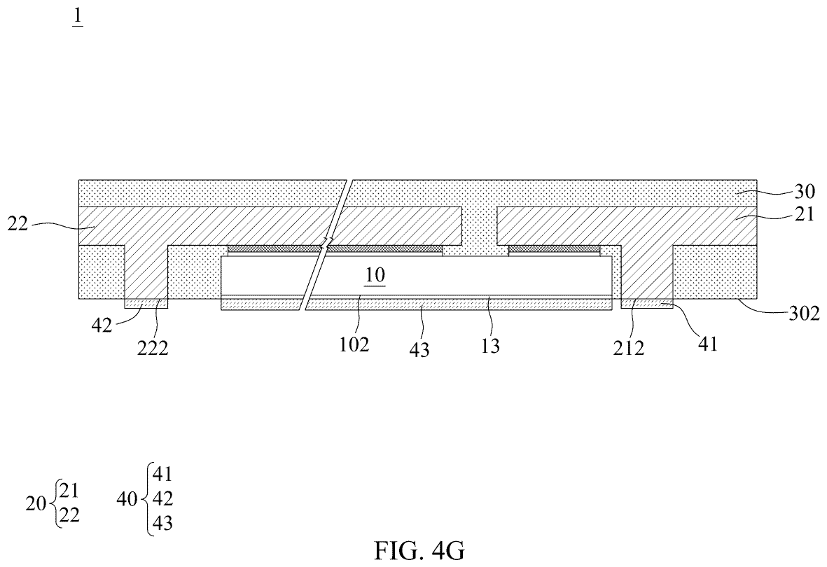

FIG. 4A, FIG. 4B, FIG. 4C, FIG. 4D, FIG. 4E, FIG. 4F, FIG. 4G, and FIG. 4H illustrate one or more operations of a method for manufacturing a package structure 1, in accordance with some embodiments of the present disclosure.

Referring to FIG. 4A, a leadframe 20 is provided with one or more masks 61 and 62 disposed thereon. The leadframe 20 may include a first lead 21′ and a second lead 22′. The first lead 21′ and the second lead 22′ may be rectangular. The masks 61 and 62 may be disposed on the surfaces 212 and 222 to protect those not to be etched. In some embodiments, the masks 61 and 62 may be any material that is capable of resisting etching. In some embodiments, the first lead 21′ and the second lead 22′ may be disposed on a carrier (not shown).

Referring to FIG. 4B, etching is performed on the first lead 21′ and the second lead 22′ to form the first lead 21 and second lead 22 with specific shapes. In some embodiments, etching may be half-etching. The first lead 21 is etched to form a first portion 21a and a second portion 21b protruding from the first portion 21a. In some embodiments, the first lead 21 may be etched from the surface 212 to the surface 213. The distance between the surfaces 212 and 213 may be controlled by etching. In some embodiments, the surface 213 and lateral surface 214 are etched surfaces, and thus they have a roughness different from the surface 212. The second lead 22 is etched to form a first portion 22a and a second portion 22b protruding from the first portion 22a. In some embodiments, the second lead 22 may be etched from the surface 222 to the surface 223. The distance between the surfaces 222 and 223 may be controlled by etching. In some embodiments, the surface 223 and lateral surface 224 are etched surfaces, and thus they have a roughness different from the surface 222. In some embodiments, the first lead 21 and the second lead 22 may be disposed on a carrier (not shown) to perform etching.

Referring to FIG. 4C, the masks 61 and 62 are removed, and then the solder materials 11S may be disposed on the surface 213 of the first lead 21 and the solder materials 12S may be disposed on the surface 223 of the second lead 22. In some embodiments, the solder materials 11S and 12S are disposed apart from the edge of the leadframe 20.

Referring to FIG. 4D, the die 10 is disposed on and attached on the leadframe 20. In some embodiments, the gate 11 of the die 10 is connected to the surface 213 of the first lead 21 through the solder material 11S. The source 12 of the die 10 is connected to the surface 223 of the second lead 22 through the solder material 12S. The solder materials 11S and 12S may be arranged in a predetermined pattern corresponding to the gate 11 and source 12 of the die 10. In some embodiments, the drain 13 may be substantially align with the surface 212 of the first lead 21 and the surface 222 of the second lead 22.

Referring to FIG. 4E, the semi-structure may be upside down and disposed on and adhered to a tape 65. In some embodiments, the surface 102 of the die 10 may face the tape 65 and the drain 13 of the die 10 may be disposed on the tape 65. The surface 212 of the first lead 21 and the surface 222 of the second lead 22 may be disposed on and adhered to the tape 65.

Referring to FIG. 4F, an encapsulant 30 may be formed by the molding process. The encapsulant 30 may encapsulate and protect the first lead 21, the second lead 22, and the die 10. In some embodiments, the encapsulant 30 may cover the surface 101 of the die 10 and fill the space between the leadframe 20 and the die 10. In some embodiments, the encapsulant 30 may cover the surfaces 211, 213, and 214 of the first lead 21 and the surfaces 221, 223, and 224 of the second lead 22. The encapsulant 30 may expose the surface 215 of the first lead 21 and the surface 225 of the second lead 22. In some embodiments, the encapsulant 30 may have a top surface 301 and a bottom surface 302 opposite to the top surface 301. The top surface 301 of the encapsulant 30 may be above the surface 211 of the first lead 21 and the surface 221 of the second lead 22. In some embodiments, the bottom surface 302 of the encapsulant 30 may be coplanar with the top surface of the tape 65 and the surface 212 of the first lead 21 and the surface 222 of the second lead 22.

Referring to FIG. 4G, the tape 65 may be removed; the conductive layer 40 may be disposed on the surface 102 of the die 10, the surface 212 of the first lead 21, and the surface 222 of the second lead 22, and then a singulation process (such as sawing) may be performed. Then, a package structure 1 as described and illustrated with reference to FIGS. 1A to 1D is formed. In some embodiments, the conductive layer 40 may include a first portion 41 disposed on the surface 212 of the first lead 21, a second portion 42 disposed on the surface 222 of the second lead 22, and a third portion 43 disposed on the surface 102 of the die 10.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a die comprising a first surface and a second surface opposite to the first surface, wherein the die includes a gate and a source on the first surface and a drain on the second surface;
a leadframe comprising a first lead connected to the gate and a second lead connected to the source; and
an encapsulant covering a lateral surface of the die and exposing the second surface of the die.

2. The package structure of claim 1, wherein the first lead includes a first portion connected to the gate and a second portion connected to the first portion and extending toward the second surface of the die.

3. The package structure of claim 2, wherein the first lead is a T-shape in a cross-sectional view.

4. The package structure of claim 1, wherein the first lead and the second lead define a gap, wherein the encapsulant is disposed over and covers the gap.

5. The package structure of claim 4, wherein the leadframe has a top surface opposite to the bottom surface and covered by the encapsulant.

6. The package structure of claim 5, wherein the first portion of the first lead has a lateral surface exposed by the encapsulant.

7. The package structure of claim 1, wherein the encapsulant has a second surface substantially aligned with the second surface of the die.

8. The package structure of claim 1, further comprising a conductive layer disposed on a bottom surface of the first lead that is exposed by the encapsulant.

9. The package structure of claim 2, wherein the conductive layer protrudes from the encapsulant.

10. The package structure of claim 2, wherein the drain of the die is covered by the conductive layer.

11. The package structure of claim 1, wherein a first area of the first lead is less than a second area of the second lead in a top view.

12. A package structure, comprising:
a power die comprising a gate, a source, and a drain; and
a leadframe having a cavity accommodating the power die, wherein a roughness of a bottom surface of the leadframe is different from a roughness of an inner surface of the cavity of the leadframe, wherein the gate and the source of the power die face the inner surface of the cavity.

13. The package structure of claim 12, wherein a depth of the cavity of the leadframe is greater than a thickness of the power die in a cross-sectional view.

14. The package structure of claim 12, wherein the leadframe has a lateral surface having a roughness less than the roughness of the inner surface of the cavity of the leadframe.

15. The package structure of claim 12, wherein the bottom surface of the leadframe is substantially aligned with a bottom surface of the power die.

16. The package structure of claim 12, wherein the leadframe includes a first lead connected to the gate and a second lead connected to the source, wherein the package structure further comprises a first conductive layer disposed on a bottom surface of the first lead, and a second conductive layer disposed on a bottom surface of the second lead and spaced apart from the first conductive layer.

17. The package structure of claim 16, further comprising a third conductive layer disposed on the drain of the power die and spaced apart from the first conductive layer.

18. A package structure, comprising:
a leadframe having a cavity, wherein an inner surface of the cavity of the leadframe has a plurality of recesses; and
a power die accommodated in the cavity of the leadframe, the power die comprising a gate and a source facing the plurality of recesses.

19. The package structure of claim 18, wherein the leadframe includes a first lead, the first lead includes a first portion connected to the source of the power die and a second portion connected to the first portion and extending away from the first portion, wherein the first portion has a surface facing the power die and having a plurality of recesses.

20. The package structure of claim 18, wherein the leadframe includes a second lead, the second lead includes a third portion connected to the gate of the power die and a fourth portion connected to the third portion and extending away from the third portion, wherein the fourth portion has a minimum width at where the fourth portion connecting the third portion in a cross-sectional view.
